(19) United States
(12) Patent Application Publication
(10) Pub. No.: US 2003/0082857 A1
(43) Pub. Date: May 1, 2003

(54) Method of processing a semiconductor wafer and preprocessed semiconductor wafer

(76) Inventors: Tim Stanley, Austin, TX (US); John Maltabes, Austin, TX (US); Karl Mautz, Round Rock, TX (US)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 10/033,071

(22) Filed: Oct. 26, 2001

(51) Int. Cl. H01L 21/00; H01L 21/8234; H01L 21/8244

(52) U.S. Cl. 438/151; 29/25.01; 438/238

(57) ABSTRACT

A method of processing a semiconductor wafer (10) is provided. The method comprises the steps of: providing a semiconductor wafer (10) as a semiconductor substrate (12), preprocessing the semiconductor wafer (10) by depositing on the semiconductor wafer (10) at least one additional layer (14, 16), and further processing the preprocessed semiconductor wafer (10). The preprocessing is accomplished in a first factory (18) and the further processing is accomplished in a second factory (20). The present invention is further related to a preprocessed semiconductor wafer (10) an to a system for processing a semiconductor wafer (10).

### FIELD OF THE INVENTION

The present invention generally relates to a method of processing a semiconductor wafer. In particularly, the present invention relates to a method of preprocessing and further processing a semiconductor wafer. Further, the present invention relates to a preprocessed semiconductor wafer. Moreover, the present invention is related to a system for processing a semiconductor wafer.

### BACKGROUND OF THE INVENTION

The processing of semiconductor wafers usually involves a large number of processing steps. These processing steps comprise for example diffusion, thermal processing, ion implantation, lithography steps, etching, deposition, epitaxial growth, and many more. The various processing steps have different nature. For example, it can be relatively simple to grow an oxide on a semiconductor surface; in contrast thereto, it may be very complicated to perform a patterning by lithography steps. Thus, there are very different requirements with respect to the different manufacturing steps. Further, an alignment that is related to critical pattern definition steps is probably complicated because of batch processing before such critical steps; in other words: the various steps influence each other.

The present invention seeks to solve the above mentioned problems by providing a new method and a new system of processing a semiconductor wafer.

### BRIEF DESCRIPTION OF THE DRAWINGS

FIG. 1 is a schematic illustration of a system according to the present invention;

FIG. 2 is a block diagram illustrating a method according to the present invention;

FIG. 3 is a schematic cross sectional view illustrating a first process step according to the present invention;

FIG. 4 is a schematic cross sectional view illustrating a second process step according to the present invention;

FIG. 5 is a schematic cross sectional view illustrating a third process step according to the present invention; and

FIG. 6 is a schematic cross sectional view illustrating a fourth process step according to the present invention.

### DETAILED DESCRIPTION OF PREFERRED EMBODIMENTS

According to the present invention, a method of processing a semiconductor wafer 10 is provided comprising the steps of:

providing a semiconductor wafer 10 as a semiconductor substrate 12,

preprocessing the semiconductor wafer 10 by depositing on the semiconductor wafer at least one additional layer 14, 16, and

further processing the preprocessed semiconductor wafer 10,

wherein

the preprocessing is accomplished in a first factory 18, and

the further processing is accomplished in a second factory 20.

Further, the present invention provides a preprocessed semiconductor wafer 10 for further processing

the preprocessed semiconductor wafer 10 having on a semiconductor substrate at least one additional layer 14, 16 generated in a first factory 18, and

the preprocessed semiconductor wafer 10 being designated for further processing in a second factory 20.

Moreover, the present invention provides a system for processing a semiconductor wafer 10 comprising

means 28 for providing a semiconductor wafer 10 as a semiconductor substrate 12,

means 30 for preprocessing the semiconductor wafer 10 by depositing on the semiconductor wafer at least one additional layer 14, 16, and

means 32 for further processing the preprocessed semiconductor wafer,

wherein

the means 30 for preprocessing are located in a first factory 18, and

the means 32 for further processing are located in a second factory 20.

There are several advantages related to the embodiments of the present invention.

For example, the processing scheme allows all front-end batch processes, i.e. film deposition processes, to be run as a combined series in the first factory 18. There are no single process steps required. The single process steps occur after the front-end batch processes in the second factory 20.

It is possible to store the preprocessed semiconductor wafers for later use as a starting point for device lot manufacturing.

For example, a factory 18 optimized for large batches could grow a gate oxide and deposit the polysilicon gate material. Then, the semiconductor factory 20 could be optimized for single wafer processing with the possibility of improved cycle time and increased integration capability. Thus, a reduction or elimination of thermal batch steps in the second factory 20 results in improved cycle time, a reduced delivery time variability, and improved integration possibility. The critical pattern definition steps come first during further processing in the second factory 20, resulting in reduced alignment requirements. The processing is simplified, which leads to lower costs and shorter cycle time. Further, the lithographic requirements are reduced, which also leads to lower costs and shorter cycle time.

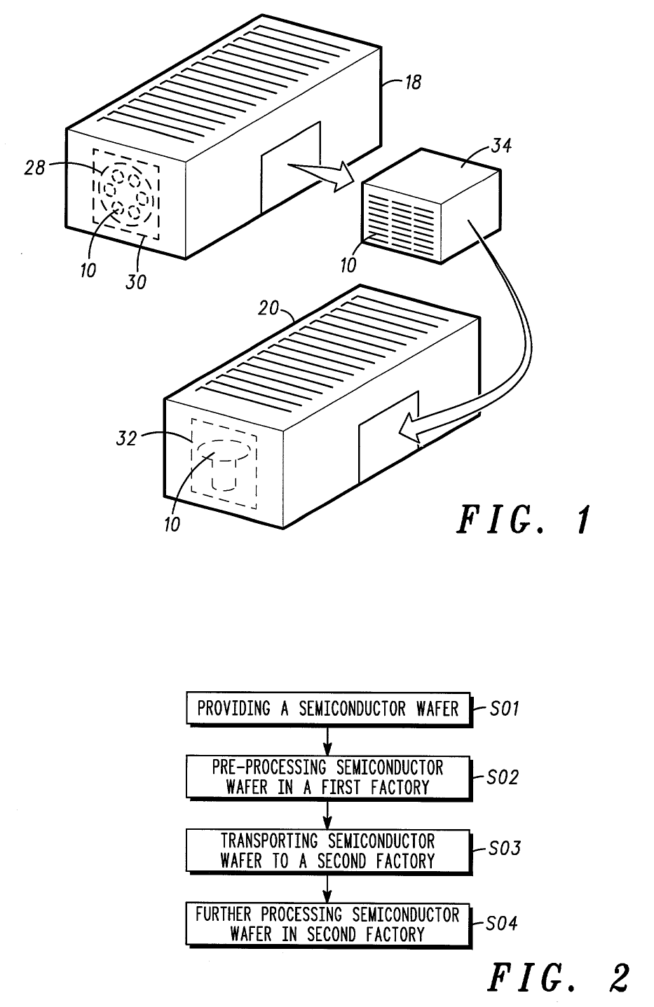

FIG. 1 is a schematic illustration of a system according to the present invention. In a first factory 18 several semiconductor wafers 10 are provided as a batch on a holder 28. The semiconductor wafers 10 are located in a chamber 30 in which they are thermally preprocessed. For example, a gate oxide is grown on the wafers 10 inside the chamber 30. Further preprocessing steps can be performed in the first factory 18, for example a deposition of a polysilicon layer on the gate oxide layer. The preprocessed semiconductor wafers 10 may then be stored inside the first factory 18 or at any other place. After a certain storing time after preprocessing or immediately after preprocessing the semiconductor wafers 10 are transported in a container 34 to a second factory 20. In this factory the preprocessed semiconductor wafers 10 are further processed, for example inside a chamber 32 for projection-gas immersion laser doping (P-GILD).

Thus, the first factory 18 can be optimized with respect to the thermal preprocessing steps. In contrast thereto, the second factory 20 can be optimized with respect to the further processing.

FIG. 2 shows a block diagram illustrating a preferred method according to the present invention. In a first step S01, a semiconductor wafer 10 is provided. In a second step S02 the semiconductor wafer 10 is preprocessed. This preprocessing takes place in a first factory 18. After that, in a third step S03, in particular after a certain storage time of the preprocessed semiconductor wafer 10, the preprocessed semiconductor wafer 10 is transported to a second factory 20. In a fourth step S04 the semiconductor wafer is further processed in the second factory 20.

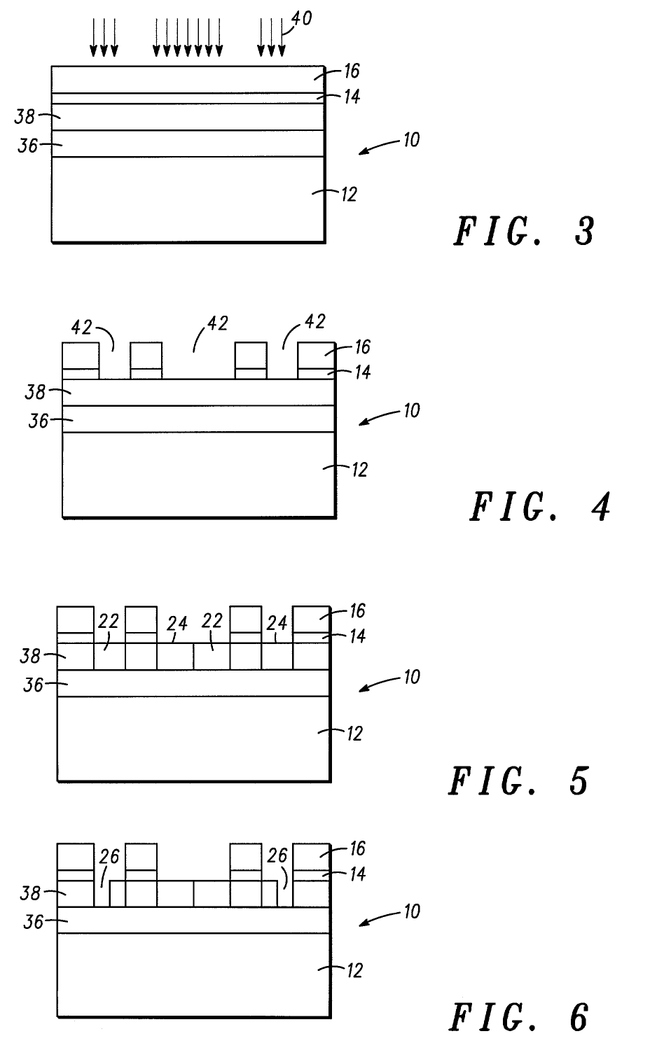

FIG. 3 to 6 show process steps for further processing a preprocessed semiconductor wafer 10 according to the present invention. The illustrated example refers to a processing sequence for a logic structure. For memory applications a different processing sequence will be used as discussed further below.

In the example according to FIG. 3 to 6 a semiconductor wafer 10 with a buried oxygen layer is used as a substrate 12 (SOI). The SOI substrate may be formed by implanting oxygen, followed by high temperature annealing to form the buried layer 36. Alternatively, different semiconductor wafers can be used, for example bare silicon wafers, wafers with an EPI surface, or GaAs substrates. On the surface silicon layer 38 of the semiconductor wafer 10 a gate oxide layer 14 is grown and a polysilicon layer 16 is deposited. Thus, the lower three layers of the structure shown in FIG. 3 represent a preprocessed semiconductor wafer 10 according to the present invention.

As a first further processing step, as shown in FIG. 3, the semiconductor wafer is differentially exposed 40 with a P-GILD process (in situ laser doping). Thereby, the undoped polysilicon layer 16 is selectively doped using masks or programmed exposure areas.

As shown in FIG. 4, a gate polysilicon etch to form etched regions 42 would be performed in a separate chamber using a chemistry that has high selectivity to undoped polysilicon.

As shown in FIG. 5, source regions 22 and drain regions 24 can then be implanted by using a P-GILD process. In this way, the regions are self-aligned based on the design. The doping can be done by first lightly doping to form p regions, followed by counter doping to form n regions. Optionally, a tungsten silicide film can be added for the device speed requirements. This can also done by a P-GILD process to add silicide films on the remaining polysilicon only.

As shown in FIG. 6, isolation regions 26 can be added. Also this can be achieved by P-GILD techniques using oxygen, the regions being defined while dopants are being inserted. After that, a rapid thermal process (RTP) could be used to grow oxide in substrate-exposed regions and to thermally narrow the gate channel. In some cases, at the beginning of the process thicker polysilicon films can be deposited on the preprocessed semiconductor wafer, for example with a thickness of 1000 to 1500 Å.

The above described process would minimize the alignment error. Only a reticle alignment error for a P-GILD mask at around 5 nm may occur. As compared to prior art techniques a lower defectivity level and a lower contamination will be present due to the use of a single chamber or several chambers on a single vacuum platform.

The above processing sequence may be used in the described or an a similar way for logic or hybrid logic applications. For memory application the initial stack would include different layers, for example in the following sequence: 1. substrate, 2. oxide, 3. capacitor film, for example Ta₂O₅, 4. an oxide, oxynitride or nitride film, 5. a gate oxide layer, 6. a polysilicon layer. Alternately, the capacitor film can be surrounded by polysilicon, amorphous silicon or single crystalline silicon.

In this case of memory applications, the further processing of the preprocessed semiconductor wafer may comprise the following steps: 1. Defining a gate area. 2. Preferentially dope for etch removal, for example a vertical cylinder or ring-donut structure in the defined gate areas; this will also provide isolation and will require an etch process using high-aspect ratio chemistries (infinite selectivity). 3. Produce sidewall connections to various conductive films, such as polysilicon, within the vertical sidewall section by additional deposition and etching steps. In some cases, connections to the topside may be realize to connect films. This may require a lithography step to accomplish. 4. The capacitor film may need to be annealed with ozone to close electron holes prior to adding additional layers on top of it.

An alternate technique would use the polysilicon on gate oxide film stack on top of a substrate film, with this on top of an oxide/nitride/oxynitride film. Below this, further stack films are arranged as for memory applications. One technique to accomplish this is to use hybrid silicon bonding transfer to add bulk silicon or substrate on top of the previously produced memory structure capped with a silicon oxide film. The logic circuit structure previously defined then would be produced on the transferred substrate film. This technique could also be used to transfer a region with the logic stack (partially or fully defined before transfer) or additional memory stack on to another stack region that has the memory device previously defined. This process could be repeated until the desired device functionality is produced.

While the invention has been described in terms of particular structures, devices and methods, those of skill in the art will understand based on the description herein that it is not limited merely to such examples and that the full scope of the invention is properly determined by the claims that follow.

1. A method of processing a semiconductor wafer comprising the steps of
providing a semiconductor wafer as a semiconductor substrate,
preprocessing the semiconductor wafer by depositing on the semiconductor wafer at least one additional layer, and
further processing the preprocessed semiconductor wafer,
characterized in that
the preprocessing is accomplished in a first factory, and
the further processing is accomplished in a second factory.

2. The method according to claim 1, wherein
the first factory is optimized with respect to the preprocessing, and
the second factory is optimized with respect to the further processing.

3. The method according to claim 1, wherein the step of generating the preprocessed semiconductor wafer comprises
growing a gate oxide layer on the semiconductor wafer, and
depositing a polysilicon layer on the gate oxide layer.

4. The method according to claim 1, wherein the step of generating the preprocessed semiconductor wafer comprises
growing an oxide layer on the semiconductor wafer,
depositing a capacitor film on the oxide layer,
depositing an isolator film on the capacitor film,
growing a gate oxide layer on the isolator film, and
depositing a polysilicon layer on the gate oxide layer.

5. The method according to claim 1, wherein the step of generating the preprocessed semiconductor wafer comprises
growing a gate oxide layer on the semiconductor wafer, and
depositing a polysilicon layer on the gate oxide layer, and
wherein the step of further processing the preprocessed semiconductor wafer comprises forming a logic structure by
selectively exposing an upper surface of the preprocessed semiconductor wafer by projection-gas immersion laser doping (P-GILD),
selectively etching undoped areas of the polysilicon layer and the gate oxide layer,
implanting source regions and drain regions by P-GILD, and
adding isolation regions by using P-GILD.

6. The method according to claim 1, wherein the step of generating the preprocessed semiconductor wafer comprises
growing an oxide layer on the semiconductor wafer,
depositing a capacitor film on the oxide layer,
depositing an isolator film on the capacitor film,
growing a gate oxide layer on the isolator film, and
depositing a polysilicon layer on the gate oxide layer, and
wherein the step of further processing the preprocessed semiconductor wafer comprises forming a memory structure by
defining gate areas,
selectively doping within the gate areas by projection-gas immersion laser doping (P-GILD),
etching the gate area with infinite selectivity, thereby producing vertical sidewall sections and isolation areas, and
producing sidewall connections within the vertical sidewall sections.

7. The method according to claim 1, wherein during the further processing several projection-gas immersion laser doping (P-GILD) steps are performed in a single chamber.

8. A preprocessed semiconductor wafer for further processing
the preprocessed semiconductor wafer having on a semiconductor substrate at least one additional layer generated in a first factory, and
the preprocessed semiconductor wafer being designated for further processing in a second factory.

9. The preprocessed semiconductor wafer according to claim 8, wherein the preprocessing comprises
growing a gate oxide layer on the semiconductor wafer, and
depositing a polysilicon layer on the gate oxide layer.

10. The preprocessed semiconductor wafer according to claim 8, wherein the preprocessing comprises
growing an oxide layer on the semiconductor wafer,
depositing a capacitor film on the oxide layer,
depositing an isolator film on the capacitor film,
growing a gate oxide layer on the isolator film, and
depositing a polysilicon layer on the gate oxide layer.

11. A system for processing a semiconductor wafer comprising
means for providing a semiconductor wafer as a semiconductor substrate,
means for preprocessing the semiconductor wafer by depositing on the semiconductor wafer at least one additional layer, and
means for further processing the preprocessed semiconductor wafer,
characterized in that
the means for preprocessing are located in a first factory, and
the means for further processing are located in a second factory.

12. The system according to claim 11, wherein
the first factory is optimized with respect to the means for preprocessing, and
the second factory is optimized with respect to the means for further processing.
